(19) United States
(12) Patent Application Publication
(10) Pub. No.: US 2023/0393487 A1
(43) Pub. Date: Dec. 7, 2023

(54) A METHOD FOR MODELING MEASUREMENT DATA OVER A SUBSTRATE AREA AND ASSOCIATED APPARATUSES

(71) Applicant: ASML NETHERLANDS B.V., Veldhoven (NL)

(72) Inventors: Gijs TEN HAAF, Valkenswaard (NL); Shreya ADYANTHAYA, Eindhoven (NL)

(73) Assignee: ASML NETHERLANDS B.V., Veldhoven (NL)

(21) Appl. No.: 18/033,028

(22) PCT Filed: Nov. 9, 2021
(86) PCT No.: PCT/EP2021/081116

§ 371 Date: Apr. 20, 2023

(30) Foreign Application Priority Data
Nov. 16, 2020 (EP) 20207862.2

(51) Int. Cl. G03F 7/00; G03F 9/00; G06F 30/20

(52) U.S. Cl. CPC G03F 7/705; G06F 30/20; G03F 9/7019

(57) ABSTRACT

A method for modeling measurement data over a substrate area relating to a substrate in a lithographic process. The method includes obtaining measurement data relating to the substrate and performing a combined fitting to fit to the measurement data: at least a first interfield model which describes distortion over the substrate and a field distortion model which describes distortion within an exposure field; wherein either: the at least a first interfield model includes a radial basis function model or an elastic energy minimizing spline model; or the method further includes fitting a radial basis function model or an elastic energy minimizing spline model to a distortion residual of the combined fit of a different interfield model and the field distortion model.

### CROSS-REFERENCE TO RELATED APPLICATIONS

This application claims priority of EP application 20207862.2 which was filed on 16 Nov. 2020, and which is incorporated herein in its entirety by reference.

### FIELD

The present disclosure relates to processing of substrates for the production of, for example, semiconductor devices.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) at a patterning device (e.g., a mask) onto a layer of radiation-sensitive material (resist) provided on a substrate (e.g., a wafer).

To project a pattern on a substrate a lithographic apparatus may use radiation. The wavelength of this radiation determines the minimum size of features which can be formed on the substrate. Typical wavelengths currently in use are about 365 nm (i-line), about 248 nm, about 193 nm and about 13 nm. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of about 193 nm.

Low-k1 lithography may be used to process features with dimensions smaller than the classical resolution limit of a lithographic apparatus. In such a process, the resolution formula may be expressed as CD=k1×λ/NA, where λ is the wavelength of radiation employed, NA is the numerical aperture of the projection optics in the lithographic apparatus, CD is the “critical dimension” (generally the smallest feature size printed, but in this case half-pitch) and k1 is an empirical resolution factor. In general, the smaller k1 the more difficult it becomes to reproduce the pattern on the substrate that resembles the shape and dimensions planned by a circuit designer in order to achieve particular electrical functionality and performance. To overcome these difficulties, sophisticated fine-tuning steps may be applied to the lithographic projection apparatus and/or design layout. These include, for example, but not limited to, optimization of a numerical aperture (NA,) a customized illumination scheme, use of one or more phase shifting patterning devices, optimization of the design layout such as optical proximity correction (OPC) in the design layout, or other methods generally defined as resolution enhancement techniques (RET). Additionally or alternatively, one or more tight control loops for controlling a stability of the lithographic apparatus may be used to improve reproduction of the pattern at low k1.

Effectiveness of the control of a lithographic apparatus may depend on characteristics of individual substrates. For example, a first substrate processed by a first processing tool prior to processing by the lithographic apparatus (or any other process step of the manufacturing process, herein referred to generically as a manufacturing process step) may benefit from (slightly) different control parameters than a second substrate processed by a second processing tool prior to processing by the lithographic apparatus.

The accurate placement of patterns on the substrate is a chief challenge for reducing the size of circuit components and other products that may be produced by lithography. In particular, the challenge of measuring accurately the features on a substrate which have already been laid down is a critical step in being able to align successive layers of features in superposition accurately enough to produce working devices with a high yield. So-called overlay should, in general, be achieved within a few tens of nanometers in today's sub-micron semiconductor devices, down to a few nanometers in the most critical layers.

Consequently, modern lithography apparatuses involve extensive measurement or ‘mapping’ operations prior to the step of actually exposing or otherwise patterning the substrate at a target location. So-called advanced alignment models have been and continue to be developed to model and correct more accurately non-linear distortions of the wafer ‘grid’ that are caused by processing steps and/or by the lithographic apparatus itself. Not all distortions are correctable during exposure, however, and it remains important to trace and eliminate as many causes of such distortions as possible.

These distortions of the wafer grid are represented by measurement data associated with mark position. The measurement data are obtained from measurements of wafers. An example of such measurements are alignment measurements of alignment marks performed using an alignment system in a lithographic apparatus prior to exposure.

It would be desirable to improve modeling of these distortions.

### SUMMARY

In a first aspect of the invention there is provided a method for modeling measurement data over a substrate area relating to a substrate in a lithographic process, comprising: obtaining measurement data relating to said substrate; performing a combined fitting to fit to the measurement data: at least a first interfield model which describes distortion over the substrate and a field distortion model which describes distortion within an exposure field; wherein either: said at least a first interfield model comprises a radial basis function model which describes distortion over the substrate in terms of radial basis functions or an elastic energy minimizing spline model which describes distortion over the substrate in terms of basis functions which minimize a certain functional of the model; or said method further comprises fitting a radial basis function model which describes distortion over the substrate in terms of radial basis functions or an elastic energy minimizing spline model which describes distortion over the substrate in terms of basis functions which minimize a certain functional of the model to a distortion residual of the combined fit of a different interfield model and the field distortion model.

In a second aspect of the invention there is provided a method for modeling measurement data over a substrate area relating to a substrate in a lithographic process, comprising:
obtaining measurement data relating to said substrate; and performing a fitting to fit a field distortion model which describes distortion within an exposure field to the measurement data by minimizing a cost function comprising a regularization term which depends on parameters of said field distortion model, said regularization term relating to bending energy of the field distortion model.

In a further aspect of the invention, there is provided a computer program comprising program instructions operable to perform the method of the first aspect when run on a suitable apparatus, and associated processing apparatus and lithographic apparatus.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a schematic overview of a lithographic cell;

FIG. 3 shows schematically the use of the lithographic apparatus and lithographic cell of FIGS. 1 and 2 together with one or more other apparatuses forming a manufacturing facility for, e.g., semiconductor devices, the facility implementing a control strategy according to an embodiment of the invention;

### DETAILED DESCRIPTION

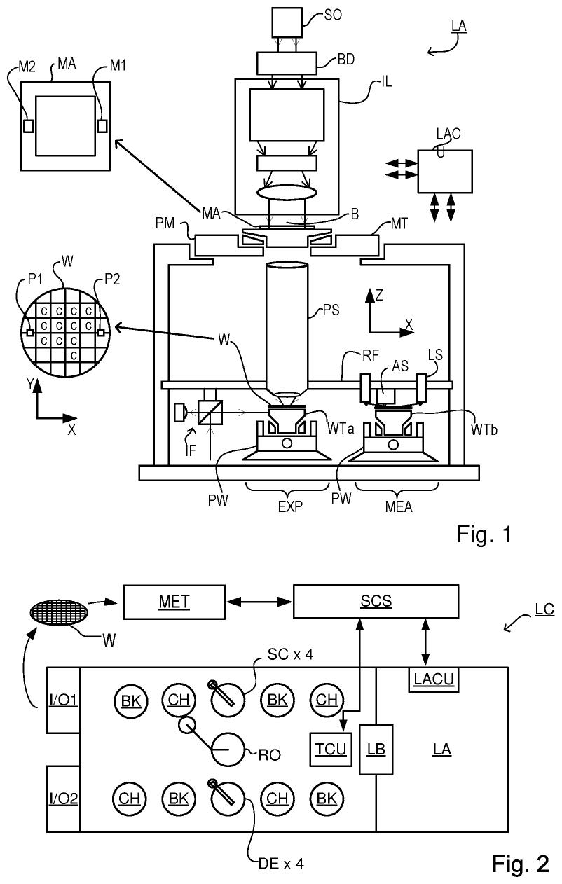

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a support (e.g., a mask table) T constructed to support a patterning device (e.g., a mask) MA and connected to a first positioner PM configured to accurately position the patterning device MA in accordance with certain parameters, one or more substrate supports (e.g., a wafer table) WTa and WTb constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

Lithographic apparatus LA in this example is of a so-called dual stage type which has two substrate tables WTa and WTb and two stations—an exposure station and a measurement station—between which the substrate tables can be moved. While one substrate on one substrate table is being exposed at the exposure station EXP, another substrate can be loaded onto the other substrate table at, e.g., the measurement station MEA or at another location (not shown) or can be processed at measurement station MEA. A substrate table with a substrate can be located at measurement station MEA so that various preparatory steps may be carried out. The preparatory steps may include mapping the surface height of the substrate using a level sensor LS and/or measuring the position of alignment marks on the substrate using an alignment sensor AS. Due to inaccuracies in creating the marks and also due to deformations of the substrate that occur throughout its processing, the set of marks may next to translation and rotation have undergone more complex transformations. Consequently, in addition to measuring position and orientation of the substrate, the alignment sensor in practice may measure in detail the positions of many marks across the substrate area, if the apparatus LA is to print product features at the correct locations with high accuracy. The measurement of alignment marks can therefore be time-consuming and the provision of two substrate tables enables a substantial increase in the throughput of the apparatus. If the position sensor IF is not capable of measuring the position of the substrate table while it is at the measurement station as well as at the exposure station, a second position sensor may be provided to enable the positions of the substrate table to be tracked at both stations. An embodiment of the invention can be applied in an apparatus with only one substrate table, or with more than two.

In addition to having one or more substrate supports, the lithographic apparatus LA may comprise a measurement stage (not shown). The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. With the aid of the second positioner PW and position sensor IF (e.g. an interferometric device, linear encoder or capacitive sensor), the substrate table WTa/WTb can be moved accurately, e.g. so as to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WTa/WTb may be realized using a long-stroke module and a short-stroke module, which form part of the second positioner PW. In the case of a stepper (as opposed to a scanner) the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The apparatus further includes a lithographic apparatus control unit LACU which controls all the movements and measurements of various actuators and sensors of the lithographic apparatus (such as those described). Control unit LACU also includes signal processing and data processing capacity to implement desired calculations relevant to the operation of the apparatus. In practice, control unit LACU will be realized as a system of many sub-units, each handling the real-time data acquisition, processing and control of a subsystem or component within the apparatus. For example, one processing subsystem may be dedicated to servo control of the substrate positioner PW. Separate units may even handle coarse and fine actuators, or different axes. Another unit might be dedicated to the readout of the position sensor IF. Overall control of the apparatus may be controlled by a central processing unit, communicating with these sub-systems processing units, with operators and with other apparatuses involved in the lithographic manufacturing process.

As shown in FIG. 2 the lithographic apparatus LA may form part of a lithographic cell LC, also sometimes referred to as a lithocell or (litho)cluster, which often also includes apparatuses to perform pre- and post-exposure processes on a substrate W. Conventionally these apparatuses includes one or more spin coaters SC to deposit resist layers, one or more developers DE to develop exposed resist, one or more chill plates CH and one or more bake plates BK, e.g. for conditioning the temperature of substrates W e.g. for conditioning solvents in the resist layers. A substrate handler, or robot, RO picks up substrates W from input/output ports I/O1, I/O2, moves them between the different processing apparatuses and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g. via lithography control unit LACU.

In order for the substrates W exposed by the lithographic apparatus LA to be exposed correctly and consistently, it is desirable to inspect substrates to measure properties of patterned structures, such as overlay errors between subsequent layers, line thicknesses, critical dimensions (CD), etc. For this purpose, one or more inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus MET, which may also be referred to as a metrology apparatus or metrology tool, is used to determine one or more properties of the substrates W, and in particular, how one or more properties of different substrates W vary or how one or more properties associated with different layers of the same substrate W vary from layer to layer. The inspection apparatus may be constructed to identify defects on the substrate W and may, for example, be part of the lithocell LC, or may be integrated into the lithographic apparatus LA, or may even be a stand-alone device. The inspection apparatus may measure the one or more properties on a latent image (an image in a resist layer after the exposure), or on a semi-latent image (an image in a resist layer after a post-exposure bake step), or on a developed resist image (in which the exposed or unexposed parts of the resist have been removed), or even on an etched image (after a pattern transfer step such as etching).

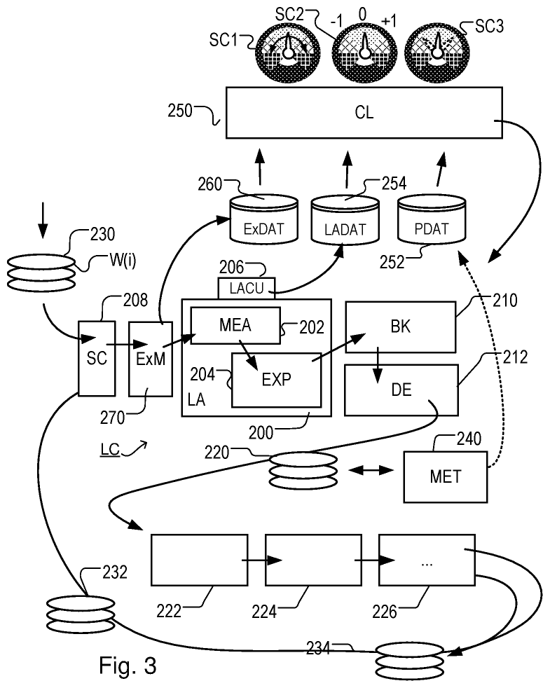

FIG. 3 shows the lithographic apparatus LA and the lithocell LC in the context of an industrial manufacturing facility for, e.g., semiconductor products. Within the lithographic apparatus (or “litho tool” 200 for short), the measurement station MEA is shown at 202 and the exposure station EXP is shown at 204. The control unit LACU is shown at 206. As already described, litho tool 200 forms part of a “litho cell” or “litho cluster” that also includes a coating apparatus SC, 208 for applying photosensitive resist and/or one or more other coatings to substrate W for patterning by the apparatus 200. At the output side of apparatus 200, a baking apparatus BK, 210 and developing apparatus DE, 212 are provided for developing the exposed pattern into a physical resist pattern. Other components shown in FIG. 3 are omitted, for clarity.

Once the pattern has been applied and developed, patterned substrates 220 are transferred to other processing apparatuses such as are illustrated at 222, 224, 226. A wide range of processing steps are implemented by various apparatuses in a typical manufacturing facility. For the sake of example, apparatus 222 in this embodiment is an etching station, and apparatus 224 performs a post-etch annealing step. Further physical and/or chemical processing steps are applied in further apparatuses, 226, etc. Numerous types of operation can be required to make a real device, such as deposition of material, modification of surface material characteristics (oxidation, doping, ion implantation etc.), chemical-mechanical polishing (CMP), and so forth. The apparatus 226 may, in practice, represent a series of different processing steps performed in one or more apparatuses.

The described semiconductor manufacturing process comprising a sequence of patterning process steps is just one example of an industrial process in which the techniques disclosed herein may be applied. The semiconductor manufacturing process includes a series of patterning steps. Each patterning process step includes a patterning operation, for example a lithographic patterning operation, and a number of other chemical and/or physical operations.

The manufacture of semiconductor devices involves many repetitions of such processing, to build up device structures with appropriate materials and patterns, layer-by-layer on the substrate. Modern device manufacturing processes may comprise 40 or 50 individual patterning steps, for example. Accordingly, substrates 230 arriving at the litho cluster may be newly prepared substrates, or they may be substrates that have been processed previously in this cluster 232 or in another apparatus entirely. Similarly, depending on the required processing, substrates on leaving apparatus 226 may be returned for a subsequent patterning operation in the same litho cluster (such as substrates 232), they may be destined for patterning operations in a different cluster (such as substrates 234), or they may be finished products to be sent for dicing and packaging (such as substrates 234).

Each layer of the product structure typically involves a different set of process steps, and the apparatuses used at each layer may be completely different in type. Further, even where the processing steps to be applied by the apparatuses are nominally the same, in a large facility, there may be several supposedly identical machines working in parallel to perform the processing on different substrates. Small differences in set-up or faults between these machines can mean that they influence different substrates in different ways. Even steps that are relatively common to each layer, such as etching (apparatus 222) may be implemented by several etching apparatuses that are nominally identical but working in parallel to maximize throughput. Parallel processing may also be performed in different chambers within a larger apparatus. Moreover, in practice, different layers often involve different etch processes, for example chemical etch, plasma etch, etc., according to the details of the material to be etched, and special requirements such as, for example, anisotropic etching.

The previous and/or subsequent processes may be performed in other lithography apparatuses, as just mentioned, and may even be performed in different types of lithography apparatus. For example, one or more layers in the device manufacturing process which are very demanding in terms of, e.g., resolution and/or overlay may be performed in a more advanced lithography tool than one or more other layers that are less demanding. Therefore, one or more layers may be exposed in an immersion type lithography tool, while one or more others are exposed in a ‘dry’ tool. One or more layers may be exposed in a tool working at DUV wavelengths, while one or more others are exposed using EUV wavelength radiation.

Also shown in FIG. 3 is the metrology apparatus (MET) 240 which is provided for making measurements of parameters of the products at desired stages in the manufacturing process. A common example of a metrology station in a modern lithographic manufacturing facility is a scatterometer, for example an angle-resolved scatterometer or a spectroscopic scatterometer, and it may be applied to measure one or more properties of developed substrates at 220 prior to etching in the apparatus 222. Using metrology apparatus 240, performance parameter data PDAT 252 may be determined. From this performance parameter data PDAT 252, it may be further determined that a performance parameter, such as overlay or critical dimension (CD), does not meet specified accuracy requirements in the developed resist. Prior to the etching step, the opportunity exists to strip the developed resist and reprocess one or more of the substrates 220 through the litho cluster. Moreover, the metrology results from the metrology apparatus 240 can be used to maintain accurate performance of the patterning operations in the litho cluster, by making small adjustments over time, thereby reducing or minimizing the risk of products being made out-of-specification, and requiring re-work. Of course, metrology apparatus 240 and/or one or more other metrology apparatuses (not shown) can be applied to measure one or more properties of the processed substrates 232, 234, and/or of incoming substrates 230.

Typically the patterning process in a lithographic apparatus LA is one of the most significant steps in the processing which involves high accuracy of dimensioning and placement of structures on the substrate W. To help ensure this high accuracy, three systems may be combined in a control environment as schematically depicted in FIG. 3. One of these systems is the litho tool 200 which is (virtually) connected to a metrology apparatus 240 (a second system) and to a computer system CL 250 (a third system). A desire of such an environment is to optimize or improve the cooperation between these three systems to enhance an overall so-called “process window” and provide one or more tight control loops to help ensure that the patterning performed by the lithographic apparatus LA stays within a process window. The process window defines a range of values of a plurality of process parameters (e.g. two or more selected from dose, focus, overlay, etc.) within which a specific manufacturing process yields a defined result (e.g. a functional semiconductor device)—typically a range within which the values of the process parameters in the lithographic process or patterning process are allowed to vary while yielding a proper structure (e.g., specified in terms of an acceptable range of CD (such as +−10% of a nominal CD)).

The computer system CL may use (part of) the design layout to be patterned to predict which one or more resolution enhancement techniques to use and to perform computational lithography simulations and calculations to determine which patterning device layout and lithographic apparatus settings achieve a largest overall process window of the patterning process (depicted in FIG. 3 by the double arrow in the first dial SC1). Typically, the resolution enhancement techniques are arranged to match the patterning possibilities of the lithographic apparatus LA. The computer system CL may also be used to detect where within the process window the lithographic apparatus LA is currently operating (e.g. using input from the metrology tool MET) to predict whether defects may be present due to e.g. sub-optimal processing (depicted in FIG. 3 by the arrow pointing “0” in the second dial SC2).

The metrology tool MET may provide input to the computer system CL to enable accurate simulations and predictions, and may provide feedback to the lithographic apparatus LA to identify possible drifts, e.g. in a calibration status of the lithographic apparatus LA (depicted in FIG. 3 by the multiple arrows in the third dial SC3).

Computer system 250 can implement control of the process based on a combination of (i) “pre-processing metrology data” (e.g., including scanner metrology data LADAT 254, and External pre-processing metrology ExDAT 260), associated with substrates before they are processed in a given processing step (for example a lithography step) and (ii) performance data or “post-processing data” PDAT 252 that is associated with the substrates after they have been processed.

A first set of pre-processing metrology data LADAT 254 (referred to herein as scanner metrology data, as it is data generated by the lithographic apparatus LA 200 or scanner) may comprise the alignment data conventionally obtained by the lithographic apparatus LA 200 using alignment sensor AS in the measurement station 202. Alternatively, or in addition to the alignment data, the scanner metrology data LADAT 254 may include height data obtained using level sensor LS, and/or “wafer quality” signals from the alignment sensor AS or the like. As such, the scanner metrology data LADAT 254 may comprise an alignment grid for the substrate, and data relating to substrate deformation (flatness). For example, the scanner metrology data LADAT 254 may be generated by the measurement station MEA 202 of twin stage lithographic apparatus LA 200 (e.g., as this typically comprises the alignment sensor and leveling sensor) in advance of exposure, enabling simultaneous measurement and exposure operations. Such twin stage lithographic apparatus are well known.

Increasingly, (e.g. stand-alone) external pre-exposure metrology tools ExM 270 are used to make measurements before exposure on a lithographic apparatus. Such external pre-exposure metrology tools ExM 270 are distinct from the measurement station MEA 202 of a twin stage lithographic apparatus LA 200. Any pre-exposure measurements performed within the track are also considered to be external measurements. To maintain exposure throughput at a sufficient level, the scanner metrology data LADAT (e.g., alignment grid and substrate deformation grid) measured by measurement station MEA 202 is based on a sparser set of measurements as would be desirable. This typically means such a measurement station is incapable of gathering sufficient measurement data for higher order corrections, and particularly corrections beyond the third order. In addition to this, use of an opaque hard mask can make it difficult to accurately measure the wafer grid in alignment.

External pre-exposure metrology tools ExM 270 enable much denser measurements to be made on each substrate, prior to exposure. Some of these pre-exposure metrology tools ExM 270 measure and/or predict wafer grid deformation at a throughput equal to or faster than the scanner, and with a measurement density much higher than can be achieved using an alignment sensor and level sensor, even when such sensors are comprised within a separate measurement station MEA 202. Pre-exposure metrology tools comprise, for example, substrate shape inspection tools and/or stand-alone alignment stations.

While FIG. 3 shows separate storage 252, 254, 260 for each of the performance data PDAT, scanner metrology data LADAT and external pre-exposure data ExDAT, it will be appreciated that these different types of data may be stored in one common storage unit, or may be distributed over a larger number of storage units, from which particular items of data can be retrieved when required.

To represent alignment measurements over a wafer and/or over a field, an alignment model is used. A first purpose of an alignment model is to provide a mechanism for interpolating and/or extrapolating the available measurements data over the whole wafer, such that an expose grid can be created on each exposure field. The measurement data will be sparse as it is simply not practical to measure as many measurement regions as would be desirable from an overlay accuracy perspective: the time and therefore throughput overhead would be too high. A second purpose of an alignment model is to provide noise suppression. This may be achieved by using fewer model parameters than measurements or by using regularization.

While standard models might use fewer than ten parameters, advanced alignment models typically use more than 15 parameters, or more than 30 parameters. Examples of advanced models are higher order wafer alignment (HOWA) models and radial basis function (RBF) based alignment models. HOWA is a published technique based on second and higher order polynomial functions. RBF modeling is described in US2012218533A1, which is incorporated herein by reference. Different versions and extensions of these advanced models can be devised. The advanced models generate a complex description of the wafer grid that is corrected for, during the exposure of the target layer. RBF and latest versions of HOWA provide particularly complex descriptions based on tens of parameters. This implies many measurements are required to obtain a wafer grid with sufficient accuracy.

At present, polynomial based models, such as HOWA models, are predominately used for both the interfield and intrafield wafer deformation modeling. This is typically done in a cascaded manner where intrafield modelling is performed on the residual wafer deformation after interfield modelling. For example, interfield modelling may be first performed on a first set of measurements; typically, an interfield layout comprising alignment marks at a single intrafield location across the wafer (i.e., at the same location within a field, for each field of a wafer in which a mark is measured). The result of the interfield modeling is then applied to a second set of measurements; typically comprising a common intrafield layout of a plurality of marks on each of a small subset of fields on the wafer (the intrafield layout). After this, the intrafield model is fitted in the intrafield layout onto the measurements which are corrected for by the interfield model.

The downside of this cascaded way of modelling is that the measurements used for intrafield modelling are not used for the interfield modelling and vice versa which would reduce noise propagation and/or allow for more advanced models. To address this, a combined layout and a combined method of modelling is proposed for polynomial models. The combined layout samples the intrafield locations in a distributed manner, i.e., different intrafield locations are measured in different fields. Modelling an interfield model on such a layout can result in crosstalk from the intrafield deformation to the interfield model, resulting in an inaccurate wafer and field grid prediction. Therefore, a combined method of modelling has been proposed for polynomial models, in which the interfield polynomial (HOWA) basis functions and the intrafield polynomial basis functions are fitted in one go, such that the crosstalk of the interfield and intrafield polynomial correctable deformation can be prevented or mitigated.

An alternative to polynomial modeling is disclosed in US2012218533A1 (incorporated herein by reference), which is known as radial basis function (RBF) modeling. RBF modeling is an extrapolation/interpolation modeling technique able to capture localized wafer deformations better than polynomial models.

RBF modeling, as described in US2012218533A1, comprises the steps of using certain locations c̅ on the wafer (e.g. the locations of the alignment marks), referred to as centers, to generate radial basis functions, and calculating model parameters of said substrate within said apparatus using the generated radial basis functions as basis functions across said substrate. RBFs ϕ(x̅,c̅) are functions whose value depend only on the distance to some location, e.g. the origin, but in this case the locations of the centers, so that:

ϕ(x̅,c̅)=ϕ(∥x̅−c̅∥)=ϕ(r)

in which, overline indicates that the variable is a column vector and ∥⋅∥ denotes the Euclidean vector norm.

The evaluation of an RBF model on location x̅ᵢ̅ may be written as:

$$f ( \overline{{x}_{i}} ) = {\sum }_{j = 1}^{N} {w}_{j} ϕ ( ‖ \overline{{x}_{i}} - \overline{{c}_{i}} ‖ )$$

where the approximating function ƒ(x̅ᵢ̅) is represented as a weighted sum of N radial basis functions (RBFs), each associated with a different center c̅ⱼ̅ and a weight wⱼ that is the parameter to deduce from the measurements. The weights wⱼ may be computed using the least square method in which the sum of the square of the residuals mᵢ−ƒ(x̅ᵢ̅) is minimized, in which mᵢ is the measurement result (e.g. the alignment measurement in one of the two directions) on location x̅ᵢ̅. It may be noted that for the typical use case of a center located on every alignment mark there are as many weights, i.e. degrees of freedom, as there are measurements. The resulting system of equations is non-singular (invertible) under very mild conditions and therefore a unique solution exists. For many of the radial basis functions (RBFs) the only restriction is that at least 3 points are not on a straight line.

Numerous choices for RBFs are possible, such as Gaussian basis functions, inverse basis functions, multi-quadratic basis functions, inverse quadratic basis functions, spline degree k basis functions and thin plate spline basis functions. It is noted that also other RBFs are possible. Two major RBF classes are: infinitely smooth (whose derivatives exist at each point) and splines (whose derivatives may not exist in some points).

One particular RBF example is thin plate spline (TPS) modeling. TPS refers to a physical analogy involving the bending of a thin sheet of metal. In the physical setting, the deflection is in the z direction, orthogonal to the plane of the thin sheet. In order to apply this idea to the problem of substrate deformation in a lithographic process, the lifting of the plate can be interpreted as a displacement of the x or y coordinates within the plane. TPS has been widely used as a non-rigid transformation model in image alignment and shape matching. The popularity of TPS comes from a number of advantages:
the model has no free parameters that need manual tuning, automatic interpolation is feasible;
it is a fundamental solution of the two-dimensional biharmonic operator,
given a set of data points, a weighted combination of thin plate splines centered around each data point gives the interpolation function that passes through these points exactly while minimizing the so-called “bending energy.”

The mathematical details of the thin plate spline will now be provided. The thin plate spline is the model ƒ(x,y) that interpolates 1 dimensional data in such a way that the functional F(ƒ(x,y)) is minimized, where F(ƒ(x,y)) is given by

$$F ( f ( x , y ) ) = {\int }_{- ∞}^{∞} {\int }_{- ∞}^{∞} {( \frac{{\partial }^{2} f}{\partial {x}^{2}} )}^{2} + {( \frac{{\partial }^{2} f}{\partial {y}^{2}} )}^{2} + 2 {( \frac{{\partial }^{2} f}{\partial x \partial y} )}^{2} dxdy$$

and represents the so called “bending energy” of the model (in the physical setting where ƒ(x,y) describes the height of a thin plate of metal, this functional is really proportional to the bending energy related to the bending of the plate). In regularized form the thin plate spline minimizes the cost function given by:

(m̅−Kw̅−Pā)^{T}(m̅−Kw̅−Pā)+λw̅^{T}K_{C}ŵ

in which m̅ is a column vector for the measurements, K is the RBF model matrix, whose matrix elements Kᵢⱼ for the thin plate spline are given by:

Kᵢⱼ=∥x̅ᵢ̅−c̅ⱼ̅∥² ln(∥x̅ᵢ̅−c̅ⱼ̅∥)

where w̅ is a column vector comprising the RBF weights (fit parameters), P is a 1^{st} order polynomial interfield model matrix, ā is a column vector comprising the 6 linear interfield model parameters, λ is the RBF regularization parameter and w̅^{T}K_{C}w̅ is the RBF “bending energy”. The cost function may be minimized under the constraint P_{C}^{T}w̅=0̅. In the case that the centers are located on the measurement locations (K_{C}=K=K^{T}, P_{C}=P), this may be done by setting the gradient of the cost function towards the parameters w̅ and ā to zero. Re-arranging the resulting equations gives the solution which is given by

$$[ \begin{matrix}\overline{w} \\ \overline{a}\end{matrix} ] = {[ \begin{matrix}K + λ I & P \\ {P}^{T} & 0\end{matrix} ]}^{- 1} [ \begin{matrix}\overline{m} \\ \overline{0}\end{matrix} ]$$

in which I is the identity matrix. In the case of wafer alignment, the solution is calculated for the two directions (x and y) separately.

Next to being an RBF, the thin plate spline is also an example of an elastic energy minimizing spline model. The functional that is minimized is an integral of the bending energy density of the model function. Alternatively the model can be found by minimizing a different functional, e.g. an integral over a different density L that in general depends on the model function u(x,y) describing the x-direction distortion, the model function v(x,y) describing the y-direction distortion and their derivatives of any order:

L(u,v,uₓ,vₓ,u_{y},v_{y},uₓₓ,vₓₓ,u_{xy},v_{xy}, . . . )

where the subscript denotes the derivative of the function in that direction

$$( e . g . {u}_{x y} = \frac{{d}^{2} u}{dxdy} ) .$$

In order to find the basis functions that minimize this kind of functional, one can make use of the calculus of variations to derive the Euler Lagrange equations. The spline model functions may be found by finding a solution which satisfies the Euler Lagrange equations everywhere except at the center locations (x_{c},y_{c}), i.e. the solution satisfies the following set of (possibly coupled) differential equations,

$$\frac{\partial L}{\partial u} - \frac{\partial }{\partial x} \frac{\partial L}{\partial {u}_{x}} - \frac{\partial }{\partial y} \frac{\partial L}{\partial {u}_{y}} + \frac{{\partial }^{2}}{\partial {x}^{2}} \frac{\partial L}{\partial {u}_{x x}} + \frac{{\partial }^{2}}{\partial {y}^{2}} \frac{\partial L}{\partial {u}_{y y}} + \frac{{\partial }^{2}}{\partial x \partial y} \frac{\partial L}{\partial {u}_{x y}} + … = {w}_{x} δ ( x - {x}_{c} ) δ ( y - {y}_{c} )$$

$$\frac{\partial L}{\partial v} - \frac{\partial }{\partial x} \frac{\partial L}{\partial {v}_{x}} - \frac{\partial }{\partial y} \frac{\partial L}{\partial {v}_{y}} + \frac{{\partial }^{2}}{\partial {x}^{2}} \frac{\partial L}{\partial {v}_{x x}} + \frac{{\partial }^{2}}{\partial {y}^{2}} \frac{\partial L}{\partial {v}_{y y}} + \frac{{\partial }^{2}}{\partial x \partial y} \frac{\partial L}{\partial {v}_{x y}} + … = {w}_{y} δ ( x - {x}_{c} ) δ ( y - {y}_{c} )$$

in which δ denotes the Dirac delta function and wₓ and w_{y} are constants. The solution, i.e., the spline model function that is sought, will in general look like:

$$[ \begin{matrix}u ( x , y ) \\ v ( x , y )\end{matrix} ] = P \overline{a} + {\sum }_{j = 1}^{N} [ \begin{matrix}p ( x - {x}_{c , j} , x - {y}_{c , j} ) & w ( x - {x}_{c , j} , x - {y}_{c , j} ) \\ z ( x - {x}_{c , j} , x - {y}_{c , j} ) & q ( x - {x}_{c , j} , x - {y}_{c , j} )\end{matrix} ] [ \begin{matrix}{w}_{x , j} \\ {w}_{y , j}\end{matrix} ]$$

in which P is the model matrix of a model that has no effect on the value of the functional that is minimized, p, w, z, and q are the spline model basis functions and w_{x,j} and w_{y,j} are the model parameters relating to a spline center on location (x_{c,j},y_{c,j}). In case of the thin plate spline model, the functions w and z are zero and the functions p and q are the same and only depend on the distance between (x,y) and (x_{c,j},y_{c,j}), i.e., they become radial basis functions.

Using an RBF model or an elastic energy minimizing spline model in place of the HOWA interfield model in a cascaded way of modelling on a combined layout will result in crosstalk from the field distortion to the RBF model. Depending on whether regularization is used, and to what degree, this crosstalk can be more pronounced than in the case of polynomial interfield modelling. Furthermore, the typical RBF model, with a center on every measurement location, does not lend itself for the standard combined fitting approach because it is an interpolation model: it consists of as many parameters as measurements. Therefore, unless compromises are being made on the number of centers in the RBF model or elastic energy minimizing spline model, an (unconstrained) combined fit of such model and a field distortion model yields in an underdetermined system of equations.

To overcome the limitations of cascading an RBF model or elastic energy minimizing spline model and a field distortion model on a combined layout, two methods are proposed:
A combined fit of an RBF model or elastic energy minimizing spline model and the field distortion model. This fit may be solved by minimizing a cost function that includes a regularization term that depends on the RBF or elastic energy minimizing spline model parameters in addition to the residuals of the model squared, in order to yield a well determined set of equations; and optionally also includes a regularization term in the cost function that depends on the field distortion model parameters.
A cascaded fit of an RBF model or elastic energy minimizing spline model on the residuals of a combined fit of a different interfield model and the field distortion model.

By including a regularization term in the cost function that is minimized, the field distortion model parameters will be chosen such that this regularization term is minimal. The regularization term may be the “bending energy” of the interfield model. In that case the field distortion model parameters are such that the interfield model has minimal “bending energy”. The model parameters may be found by setting the gradient of the cost function towards them to zero and solving the resulting equations.

The mathematical details of an example of such an approach will now be provided. In a first example the method comprises a combined fit of the RBF model and an intrafield model by minimizing a cost function which includes a regularization term on the RBF parameters that is the RBF bending energy. For this case the cost function is given by:

(m̅−Kw̅−Pā−Lb̅)^{T}(m̅−Kw̅−Pā−Lb̅)+λw̅^{T}K_{C}w̅

where L is the intrafield model matrix and b̅ is a column vector with intrafield model parameters. The cost function again may be minimized under the constraint P_{C}^{T}w̅=0̅. In the case that the centers are located on the measurement locations (K_{C}=K=K^{T},P_{C}=P) this may be done by setting the gradient of the cost function towards the parameters w̅, ā and b̅ to zero. Re-arranging the resulting equations gives the solution:

$$[ \begin{matrix}\overline{w} \\ \overline{a} \\ \overline{b}\end{matrix} ] = {[ \begin{matrix}K + λ I & P & L \\ {P}^{T} & 0 & 0 \\ {L}^{T} & 0 & 0\end{matrix} ]}^{- 1} [ \begin{matrix}\overline{m} \\ \overline{0} \\ \overline{0}\end{matrix} ]$$

In an embodiment, an improved result may be obtained by adding an i regularization term for the field distortion model. Such a regularization may impose including a quantity in the cost function that depends on the field distortion model parameters. In an embodiment, this regularization may comprise the “bending energy” which the field distortion model induces on the intrafield grid. Alternatively, this regularization term may penalize the norm of the field distortion model coefficients, an integral of the square of the field distortion model evaluation over the field, an integral of any order of derivative of the field distortion model over the field or a different quantity that depends on the field distortion model parameters. Expressed mathematically, the cost function to be minimized now may become:

(m̅−Kw̅−Pā−Lb̅)^{T}(m̅−Kw̅−Pā−Lb̅)+λw̅^{T}Kw̅+φb̅^{T}Rb̅

where φ is the field distortion model regularization parameter, R is the field distortion model regularization matrix (bending energy example of an intrafield model given below) and b̅^{T}Rb̅ is the field distortion model regularization term. The solution is again found by setting the gradient of the cost function towards the parameters w̅, ā and b̅ to zero. Re-arranging the resulting equations gives

$$[ \begin{matrix}\overline{w} \\ \overline{a} \\ \overline{b}\end{matrix} ] = {[ \begin{matrix}K + λ I & P & L \\ {P}^{T} & 0 & 0 \\ λ {L}^{T} & 0 & - φ R\end{matrix} ]}^{- 1} [ \begin{matrix}\overline{m} \\ 0 \\ 0\end{matrix} ] .$$

The intrafield bending energy and corresponding intrafield model regularization matrix may be determined as follows. In case of a linear intrafield model (an intrafield model that can be written as a linear combination of the model parameters), an evaluation of the model at an intrafield location (x_{f},y_{f}) can be written as

$$f ( {x}_{f} , {y}_{f} , \overline{b} ) = {\sum }_{i} {b}_{i} {f}_{i} ( {x}_{f} , {y}_{f} )$$

In which bᵢ is the model parameter that corresponds to the basis function ƒᵢ(x_{f},y_{f}). The bending energy U_{f} of the intrafield model within one field may be calculated by:

$${U}_{f} = {\int }_{- {a}_{f} / 2}^{{a}_{f} / 2} {\int }_{- {b}_{f} / 2}^{{b}_{f} / 2} {( \frac{{\partial }^{2} f}{\partial {x}_{f}^{2}} )}^{2} + {( \frac{{\partial }^{2} f}{\partial {y}_{f}^{2}} )}^{2} + 2 {( \frac{{\partial }^{2} f}{\partial {x}_{f} \partial {y}_{f}} )}^{2} {dx}_{f} {dy}_{f} = {\sum }_{i} {\sum }_{j} {b}_{i} {b}_{j} {\int }_{- {a}_{f} / 2}^{{a}_{f} / 2} {\int }_{- {b}_{f} / 2}^{{b}_{f} / 2} \frac{{\partial }^{2} {f}_{i}}{\partial {x}_{f}^{2}} \frac{{\partial }^{2} {f}_{j}}{\partial {x}_{f}^{2}} + \frac{{\partial }^{2} {f}_{i}}{\partial {y}_{f}^{2}} \frac{{\partial }^{2} {f}_{j}}{\partial {y}_{f}^{2}} + 2 \frac{{\partial }^{2} {f}_{i}}{\partial {x}_{f} \partial {y}_{f}} \frac{{\partial }^{2} {f}_{j}}{\partial {x}_{f} \partial {y}_{f}} {dx}_{f} {dy}_{f}$$

in which a_{f} and b_{f} are the field size in the x- and y-direction respectively. The expression can expressed in matrix form like

U_{f}=b̅^{T}Rb̅

where the matrix elements Rᵢⱼ of the regularization matrix R are given by

$${R}_{ij} = {\int }_{- {a}_{f} / 2}^{{a}_{f} / 2} {\int }_{- {b}_{f} / 2}^{{b}_{f} / 2} \frac{{\partial }^{2} {f}_{i}}{\partial {x}_{f}^{2}} \frac{{\partial }^{2} {f}_{j}}{\partial {x}_{f}^{2}} + \frac{{\partial }^{2} {f}_{i}}{\partial {y}_{f}^{2}} \frac{{\partial }^{2} {f}_{j}}{\partial {y}_{f}^{2}} + 2 \frac{{\partial }^{2} {f}_{i}}{\partial {x}_{f} \partial {y}_{f}} \frac{{\partial }^{2} {f}_{j}}{\partial {x}_{f} \partial {y}_{f}} {dx}_{f} {dy}_{f} ,$$

in which i and j indicate the row and column index and of the matrix. For a polynomial intrafield model, the model evaluation can be written as

ƒᵢ(x_{f},y_{f})=x_{f}ⁿ^{ᵢ}y_{f}^{m}^{ᵢ}

in which nᵢ & mᵢ are the x- and y-direction powers of the i^{th} basis function. For such a model the regularization matrix elements can be approximated by:

$${R}_{ij} = \frac{4 π {r}_{w}^{2}}{{a}_{f} {b}_{f}} \{ \begin{matrix}\begin{matrix}\frac{{n}_{i} {n}_{j} ( {n}_{i} - 1 ) ( {n}_{j} - 1 )}{( {n}_{i} + {n}_{j} - 3 ) ( {m}_{i} + {m}_{j} + 1 )} \\ {( \frac{{a}_{f}}{2} )}^{{n}_{i} + {n}_{j} - 3} {( \frac{{b}_{f}}{2} )}^{{m}_{i} + {m}_{j} + 1} + … \\ \frac{{m}_{i} {m}_{j} ( {m}_{i} - 1 ) ( {m}_{j} - 1 )}{( {n}_{i} + {n}_{j} + 1 ) ( {m}_{i} + {m}_{j} - 3 )} \\ {( \frac{{a}_{f}}{2} )}^{{n}_{i} + {n}_{j} + 1} {( \frac{{b}_{f}}{2} )}^{{m}_{i} + {m}_{j} - 3} + … \\ \frac{2 {n}_{i} {n}_{j} {m}_{i} {m}_{j}}{( {n}_{i} + {n}_{j} - 1 ) ( {m}_{i} + {m}_{j} - 1 )} \\ {( \frac{{a}_{f}}{2} )}^{{n}_{i} + {n}_{j} - 1} {( \frac{{b}_{f}}{2} )}^{{m}_{i} + {m}_{j} - 1}\end{matrix} & \begin{matrix}for {n}_{i} + {n}_{j} = even \& \\ {m}_{i} + {m}_{j} = even\end{matrix} \\ 0 & \begin{matrix}for {n}_{i} + {n}_{j} = uneven \\ or {m}_{i} + {m}_{j} = uneven\end{matrix}\end{matrix} .$$

in which r_{w} is the wafer radius and the prefactor is included to go from the bending energy on a single full field to the approximated bending energy over the whole wafer.

A benefit of this combined method of fitting an RBF or elastic energy minimizing spline model and a field distortion model is that it can lead to better performance than regular RBF modelling when the to be described deformation comprises field distortion content. This is because the crosstalk from the field distortion to the RBF or elastic energy minimizing spline can be mitigated or prevented and the field distortion content can be corrected. Where no field distortion model regularization is used, the crosstalk from the field distortion correctable content to the RBF or elastic energy minimizing spline model can be fully prevented. However, this comes at the cost of a higher sensitivity to noise. With the field distortion model regularization embodiment described above, noise propagation is suppressed at the cost of some crosstalk. Therefore the model can be tuned to a use case dependent optimal performance via the hyper parameter φ.

The second method comprises performing a cascaded fit of the RBF or Elastic energy minimizing spline model on the residuals of a combined fit of a different interfield model with the field distortion model. Such a two-step method comprises first modeling the different interfield model with the field distortion model in a combined manner and subsequently modeling the RBF or elastic energy minimizing spline on the resulting residuals.

The combined fit in the first step may comprise fitting interfield polynomial (HOWA) basis functions and the field distortion model basis functions in a single fit. This fitting may be performed on a combined measurement layout such that more marks are used for interfield and field distortion modelling than presently used for each fit when fitting each individually, thereby reducing noise propagation. The combined measurement layout may comprise measurement locations distributed over the wafer, at different intrafield locations per field.

While the methods proposed above are described in terms of RBF or an elastic energy minimizing spline and a (polynomial) intrafield model, the concepts are not necessarily limited to such embodiment. For example, instead of an intrafield model describing the whole field in a continuous manner (e.g., a polynomial intrafield model), the model may be an average field model, i.e., a model that describes the average of the measurements with a translation parameter per intrafield location. In this way, the full intrafield distortion can be described at the measurement locations, thereby removing all intrafield to interfield crosstalk. By comparison, an underdetermined intrafield polynomial model always leaves an intrafield non-correctable part of the distortion that can still cause crosstalk. If an intrafield correction is required at intrafield locations different from the measurement locations, a model can be fitted on an evaluation of the average field model on the intrafield measurement grid and this model can subsequently be evaluated on any desired evaluation grid. An additional benefit of this method is that it now becomes possible to fit an interpolation model like the thin plate spline (with or without regularization) to the intrafield distortion.

The intrafield regularization (i.e., as described in the above paragraph relating to intrafield bending energy and corresponding intrafield model regularization matrix) can also be used for regularizing the fit of an intrafield model on its own, or in combination with a different interfield model. In an embodiment it can, for example, be used in a combined fit of a polynomial interfield model (like HOWA3) and a polynomial intrafield model. In that case the cost function to be minimized is given by:

(m̅−Mp̅−Lb̅)^{T}(m̅−Mp̅−Lb̅)+φb̅^{T}Rb̅

in which M and p̅ are the polynomial interfield model matrix and parameters respectively. The solution may be found by setting the gradient of the cost function towards the parameters p̅, b̅ to zero, which results in:

$$[ \begin{matrix}\overline{p} \\ \overline{b}\end{matrix} ] = {{( {[ \begin{matrix}M & L\end{matrix} ]}^{T} [ \begin{matrix}M & L\end{matrix} ] + [ \begin{matrix}0 & 0 \\ 0 & φ R\end{matrix} ] )}^{- 1} [ \begin{matrix}M & L\end{matrix} ]}^{T} \overline{m} .$$

In an embodiment the regularized model fits described above may be used to fit the model to data for which the model would be underdetermined without the regularization term included in the cost function. For example, a higher order (e.g. third order) polynomial intrafield model may with the bending energy regularization be fitted on data that contains less than ten (but more than two) intrafield location measurements (x and y position).

As an alternative to a pure intrafield distortion (i.e., a same distortion in every field), the method can also be used in combination with other field distortion models. Such alternative intrafield model may comprise: per field models that describe only the distortions of individual fields and are zero outside that field, a scan up scan down intrafield model in which the fields that are exposed in an upward travelling manner are described by a different intrafield model than the fields that are exposed in a downward travelling manner, or a trending intrafield model in which the field distortion parameters are not constant over the fields, but are a function (trend, e.g. linear) of the field sequence number.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc. In that regard, the processed “substrates” may be semiconductor wafers, or they may be other substrates, according to the type of product being manufactured.

Although specific reference may be made in this text to embodiments of the invention in the context of a lithographic apparatus, embodiments of the invention may be used in other apparatus. Embodiments of the invention may form part of a patterning device inspection apparatus, a metrology apparatus, or any apparatus that measures or processes an object such as a wafer (or other substrate) or a mask (or other patterning device). These apparatuses may be generally referred to as lithographic tools. Such a lithographic tool may use vacuum conditions or ambient (non-vacuum) conditions.

In the present document, the terms “radiation” and “beam” are used to encompass all types of radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

Although specific reference may have been made above to the use of embodiments of the invention in the context of optical lithography, it will be appreciated that the invention, where the context allows, is not limited to optical lithography and may be used in other applications, for example imprint lithography.

The terms “optimizing” and “optimization” as used herein refers to or means adjusting an apparatus (e.g., a lithography apparatus), a process, etc. such that results and/or processes have more desirable characteristics, such as higher accuracy of projection of a design pattern on a substrate, a larger process window, etc. Thus, the term “optimizing” and “optimization” as used herein refers to or means a process that identifies one or more values for one or more parameters that provide an improvement, e.g. a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Aspects of the invention can be implemented in any convenient form. For example, an embodiment may be implemented by one or more appropriate computer programs which may be carried on an appropriate carrier medium which may be a tangible carrier medium (e.g. a disk) or an intangible carrier medium (e.g. a communications signal). Embodiments of the invention may be implemented using suitable apparatus which may specifically take the form of a programmable computer running a computer program arranged to implement a method as described herein.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g. within a data center or geographically), or otherwise differently organized. The functionality described herein may be provided by one or more processors of one or more computers executing code stored on a tangible, non-transitory, machine readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

The reader should appreciate that the present application describes several inventions. Rather than separating those inventions into multiple isolated patent applications, these inventions have been grouped into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to costs constraints, some inventions disclosed herein may not be presently claimed and may be claimed in later filings, such as continuation applications or by amending the present claims. Similarly, due to space constraints, neither the Abstract nor the Summary sections of the present document should be taken as containing a comprehensive listing of all such inventions or all aspects of such inventions.

It should be understood that the description and the drawings are not intended to limit the present disclosure to the particular form disclosed, but to the contrary, the intention is to cover all modifications, equivalents, and alternatives falling within the spirit and scope of the inventions as defined by the appended claims.

Modifications and alternative embodiments of various aspects of the inventions will be apparent to those skilled in the art in view of this description. Accordingly, this description and the drawings are to be construed as illustrative only and are for the purpose of teaching those skilled in the art the general manner of carrying out the inventions. It is to be understood that the forms of the inventions shown and described herein are to be taken as examples of embodiments. Elements and materials may be substituted for those illustrated and described herein, parts and processes may be reversed or omitted, certain features may be utilized independently, and embodiments or features of embodiments may be combined, all as would be apparent to one skilled in the art after having the benefit of this description. Changes may be made in the elements described herein without departing from the spirit and scope of the invention as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an” element or “a” element includes a combination of two or more elements, notwithstanding use of other terms and phrases for one or more elements, such as “one or more.” The term “or” is, unless indicated otherwise, non-exclusive, i.e., encompassing both “and” and “or.” Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every. References to selection from a range includes the end points of the range.

In the above description, any processes, descriptions or blocks in flowcharts should be understood as representing modules, segments or portions of code which include one or more executable instructions for implementing specific logical functions or steps in the process, and alternate implementations are included within the scope of the exemplary embodiments of the present advancements in which functions can be executed out of order from that shown or discussed, including substantially concurrently or in reverse order, depending upon the functionality involved, as would be understood by those skilled in the art.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A method for modeling measurement data over a substrate area relating to a substrate in a lithographic process, the method comprising:
obtaining measurement data relating to the substrate; and
performing a combined fitting to fit to the measurement data: at least a first interfield model which describes distortion over the substrate and a field distortion model which describes distortion within an exposure field; wherein either:
the at least a first interfield model comprises a radial basis function model which describes distortion over the substrate in terms of radial basis functions or an elastic energy minimizing spline model which describes distortion over the substrate in terms of basis functions which minimize a certain model functional; or
the method further comprises fitting a radial basis function model which describes distortion over the substrate in terms of radial basis functions or an elastic energy minimizing spline model which describes distortion over the substrate in terms of basis functions which minimize a certain model functional to a distortion residual of the combined fit of a different interfield model and the field distortion model.

2. The method as claimed in claim 1, wherein the radial basis function model comprises a polyharmonic spline model.

3. The method as claimed in claim 2, wherein the polyharmonic spline model comprises a thin plate spline model.

4. The method as claimed claim 1, comprising including a regularization term in a cost function that is minimized in the fit of the radial basis function model or elastic energy minimizing spline model, where this regularization term at least depends on the parameters of the radial basis function model or elastic energy minimizing spline model.

5. The method as claimed in claim 4, wherein the regularization term is equal to the functional that is minimized.

6. The method as claimed in claim 1, comprising performing the combined fitting to fit to the measurement data: the radial basis function model and a field distortion model which describes distortion within an exposure field; and
the combined fit further comprises fitting a polynomial interfield model to the measurement data.

7. (canceled)

8. The method as claimed in claim 1, comprising fitting the radial basis function model or elastic energy minimizing spline model to a distortion residual of the combined fit of the interfield model and field distortion model, and the interfield model comprises a higher order polynomial interfield model.

9. The method as claimed in claim 1, further comprising including a regularization term which depends on field distortion model parameters, in a cost function that is minimized in the combined fitting.

10. The method as claimed in claim 9, wherein the regularization term which depends on the field distortion model parameters relates to bending energy of the field distortion model or to an integral of the square of the field distortion model over a field or the full wafer.

11. (canceled)

12. The method as claimed in claim 9, wherein in the combined fitting with the regularization term included in the cost function that is minimized is used to fit data for which the combined fit without regularization would be underdetermined.

13. The method as claimed in claim 1, wherein the combined fitting is performed on a combined measurement layout comprising measurement locations distributed over the substrate, at different intrafield locations per exposure field.

14. The method as claimed in claim 1, wherein the field distortion model comprises a polynomial intrafield model.

15. The method as claimed in claim 1, wherein the field distortion model comprises an average field model which describes the intrafield content of the measurement data with a translation parameter per intrafield location.

16. (canceled)

17. The method as claimed in claim 1, wherein the field distortion model comprises one of:
a per field model that describes the distortions of individual fields and are zero outside that field;
a scan up scan down intrafield model in which the fields that are exposed in a first direction are described by a different field distortion model than the fields exposed in a second direction;
a trending intrafield model in which parameters describing distortion per field are a function of a field sequence number.

18. A method for modeling measurement data over a substrate area relating to a substrate in a lithographic process, the method comprising:
obtaining measurement data relating to the substrate; and
performing a fitting to fit a field distortion model which describes distortion within an exposure field to the measurement data by minimizing a cost function comprising a regularization term which depends on parameters of the field distortion model, the regularization term relating to bending energy of the field distortion model.

19. The method as claimed in claim 18, wherein the fitting comprises a combined fitting performed in combination with fitting an interfield model.

20. The method as claimed in claim 18, wherein the field distortion model comprises one of:
a per field model that describes the distortions of individual fields and are zero outside that field;
a scan up scan down intrafield model in which the fields that are exposed in a first direction are described by a different field distortion model than the fields exposed in a second direction;
a trending intrafield model in which parameters describing distortion per field are a function of a field sequence number.

21. The method as claimed in claim 1, further comprising using the result of the fitting step(s) to define a grid in a positioning action of one or more substrate stages in a lithographic process.

22. The method as claimed in claim 1, further comprising measuring the substrate to obtain the measurement data.

23. (canceled)

24. A non-transient computer program carrier comprising computer program instructions therein, the instructions, when run on a suitable apparatus, configured to cause the apparatus to at least perform the method of claim 1.

25.-28. (canceled)
